(19) United States
(12) Patent Application Publication
(10) Pub. No.: US 2009/0059667 A1
(43) Pub. Date: Mar. 5, 2009

(54) MEMORY CELL ARRAY AND NON-VOLATILE MEMORY DEVICE

(75) Inventor: Ji-Ho CHO, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/198,379

(22) Filed: Aug. 26, 2008

(30) Foreign Application Priority Data
Aug. 27, 2007 (KR) 10-2007-0086021

(51) Int. Cl. G11C 16/04; G11C 8/00; G11C 16/06; G11C 5/14

(52) U.S. Cl. 365/185.11; 365/185.18; 365/230.03; 365/226; 365/185.23

(57) ABSTRACT

A memory cell array is disclosed which includes a plurality of memory banks, each memory bank including a plurality of logical sectors. The memory cell array includes a plurality of sub-memory banks, wherein each one of the plurality of sub-memory banks includes a plurality of physical sectors, and each one of the plurality of physical sectors is part of one of the plurality of logical sectors, and a plurality of sense amplifiers respectively associated with the plurality of sub-memory banks.

### CROSS REFERENCE TO RELATED APPLICATION(S)

This application claims priority under 35 USC §119 to Korean Patent Application No. 2007-86021 filed on Aug. 27, 2007, the subject matter of which is hereby incorporated by reference.

### BACKGROUND

The invention relates to a memory cell array and a nonvolatile memory device. More particularly, the invention relates to a memory cell array having independent sense amplifiers associated with sub-memory banks and a nonvolatile memory device incorporating such a memory cell array.

Semiconductor memory devices may be generally divided into volatile memory devices and non-volatile memory devices. Volatile memory devices generally store data using the logic states of bi-stable flip-flops or in relation to the presence or absence of electrical charge on a capacitor. As such, volatile memory devices lose stored data when power is interrupted.

In contrast, non-volatile memory devices, such as flash memory devices, retain stored data even when power is interrupted. Because of this performance capability, non-volatile memory devices are used to store data or programs in a wide range of applications, such as a computer, a mobile communication device, etc. Since flash memory devices are readily capable of electrically erasing and writing data, they are widely used in applications requiring frequent read/write operations. For example, flash memory devices are commonly used as data storage devices within various electronic systems.

Figure (FIG.) 1 is a block diagram illustrating a portion of a memory cell array 10 included within a conventional flash memory device. Memory cell array 10 includes a plurality of sub-memory banks (i.e., two sub-memory banks in the illustrated example). That is, memory cell array 10 includes a first sub-memory bank 12, a second sub-memory bank 14, as well as a common sense amplifier 16. In this configuration, first sub-memory bank 12 and second sub-memory bank 14 constitute one memory bank.

First sub-memory bank 12 includes a plurality of first sectors S1, S2, S3 and S4, and second sub-memory bank 14 includes a second plurality of sectors S5, S6, S7 and S8. The plurality of first sectors S1, S2, S3 and S4 is coupled to sense amplifier 16 through a first global bit line GBL, and the plurality of second sectors S5, S6, S7 and S8 is coupled to sense amplifier 16 through a second global bit line GBR. Sense amplifier 16 senses and amplifies data signals provided from the first and second pluralities of sectors S1, S2, S3, S4, S5, S6, S7 and S8, and subsequently provides amplified data signals to an input/output line IOL.

Within the conventional memory cell array 10, sense amplifier 16 may not be disposed between first sub-memory bank 12 and second sub-memory bank 14. Instead, sense amplifier 16 may be disposed to one side of the sub-memory banks due to the presence of associated circuit blocks, such as a bank driver (not shown). Thus, the electrical signal connection characteristics of memory cell array 10 may be deteriorated since a data signal provided from first sub-memory bank 12 and a data signal provided from second sub-memory bank 14 are separated communicated before amplification by common sense amplifier 16, and subsequently provided to the same input/output line IOL associated with sense amplifier 16.

To improve the electrical signal connection (or coupling) characteristics, memory cell array 10 may include a number of sense amplifiers equal to the number of sub-memory banks, such that the sub-memory banks within a constituent memory bank need not share an input/output line IOL. Thus, the sub-memory banks within a memory bank are respectively accessed by separate input/output lines using separate sense amplifiers in order to improve overall electrical signal coupling characteristics. However, flash memory devices including a plurality of sense amplifiers equal to a given number of sub-memory banks are correspondingly large in physical size. Moreover, such conventional flash memory devices also suffer from power noise problems.

### SUMMARY

In one embodiment, the invention provides a memory cell array having a plurality of memory banks, each memory bank including a plurality of logical sectors, the memory cell array comprising; a plurality of sub-memory banks, wherein each one of the plurality of sub-memory banks includes a plurality of physical sectors, and each one of the plurality of physical sectors is part of one of the plurality of logical sectors, and a plurality of sense amplifiers respectively associated with the plurality of sub-memory banks.

In another embodiment, the invention provides a non-volatile memory device, comprising; a voltage generating circuit configured to generate a program voltage or an erase voltage in response to receipt of a program control signal or an erase control signal, a row decoder configured to generate a word line drive signal based on a bank address and at least one of the program voltage and the erase voltage, a column decoder configured to generate a column select signal by decoding the bank address, and a memory cell array configured to operate in response to the word line drive signal and the column select signal, the memory cell array comprising; a plurality of sub-memory banks, each of the plurality of sub-memory banks including a plurality of physical sectors, each of the plurality of physical sectors being a part of one of the plurality of logical sectors, and a plurality of sense amplifiers respectively associated with the plurality of sub-memory banks.

### BRIEF DESCRIPTION OF THE DRAWINGS

FIG. 1 is a block diagram illustrating a memory cell array included in a conventional flash memory device.

FIG. 2 is a block diagram illustrating a memory cell array according to an embodiment of the invention.

FIG. 3 is a block diagram further illustrating an exemplary layout of sectors within the memory cell array of FIG. 2.

FIG. 4 is a circuit diagram further illustrating the memory bank of FIG. 3.

FIG. 5 is a block diagram further illustrating logical sectors of the memory bank of FIG. 3.

FIG. 6 is a diagram illustrating one exemplary layout of signal lines providing power supply voltages to sense amplifiers included within the memory cell array of FIG. 2.

FIG. 7 is a diagram illustrating another exemplary layout of signal lines providing power supply voltages to sense amplifiers included in the memory cell array of FIG. 2.

FIG. 8 is a block diagram illustrating a flash memory device including the memory cell array of FIG. 2 according to an embodiment of the invention.

### DESCRIPTION OF EMBODIMENTS

Various example embodiments will be described more fully with reference to the accompanying drawings. The invention may, however, be embodied in many different forms and should not be construed as being limited to only the illustrated embodiments. Rather, the embodiments are presented as teaching examples. Throughout the drawings and written description, like reference numerals and indicators are used to refer to like or similar elements.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

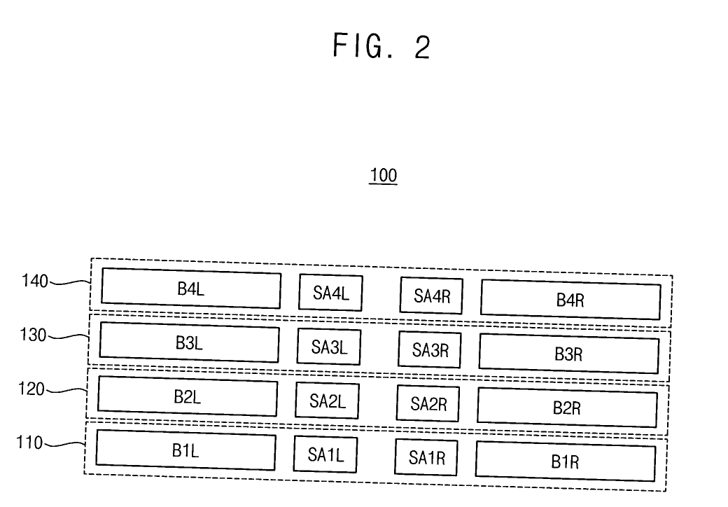

FIG. 2 is a block diagram illustrating a memory cell array 100 according to an embodiment of the invention.

Referring to FIG. 2, memory cell array 100 comprises a first memory bank 110, a second memory bank 120, a third memory bank 130 and a fourth memory bank 140. First memory bank 110 includes a first sub-memory bank B1L, a first sense amplifier SA1L, a second sub-memory bank B1R and a second sense amplifier SA1R. Second memory bank 120 includes a third sub-memory bank B2L, a third sense amplifier SA2L, a fourth sub-memory bank B2R and a fourth sense amplifier SA2R. Third memory bank 130 includes a fifth sub-memory bank B3L, a fifth sense amplifier SA3L, a sixth sub-memory bank B3R and a sixth sense amplifier SA3R, and fourth memory bank 140 includes a seventh sub-memory bank B4L, a seventh sense amplifier SA4L, an eighth sub-memory bank B4R and an eighth sense amplifier SA4R.

While memory cell array 100 illustrated in FIG. 2 as comprising four (4) memory banks, it will be understood by those skilled in the art that other memory cell arrays consistent with the teachings of the present invention may include any reasonable number of memory banks.

The first sense amplifier SA1L is functionally and exclusively associated with the first sub-memory bank B1L. In similar arrangement and operation, the second sense amplifier SA1R is associated with the second sub-memory bank B1R, the third sense amplifier SA2L with the third sub-memory bank B2L, the fourth sense amplifier SA2R with the fourth sub-memory bank B2R, the fifth sense amplifier SA3L with the fifth sub-memory bank B3L, the sixth sense amplifier SA3R with the sixth sub-memory bank B3R, the seventh sense amplifier SA4L with the seventh sub-memory bank B4L, and the eighth sense amplifier SA4R with the eighth sub-memory bank B4R.

Consistent with the foregoing, each of the sub-memory banks B1L, B1R, B2L, B2R, B3L, B3R, B4L and B4R in the illustrated example of FIG. 2 comprises a plurality of logical sectors.

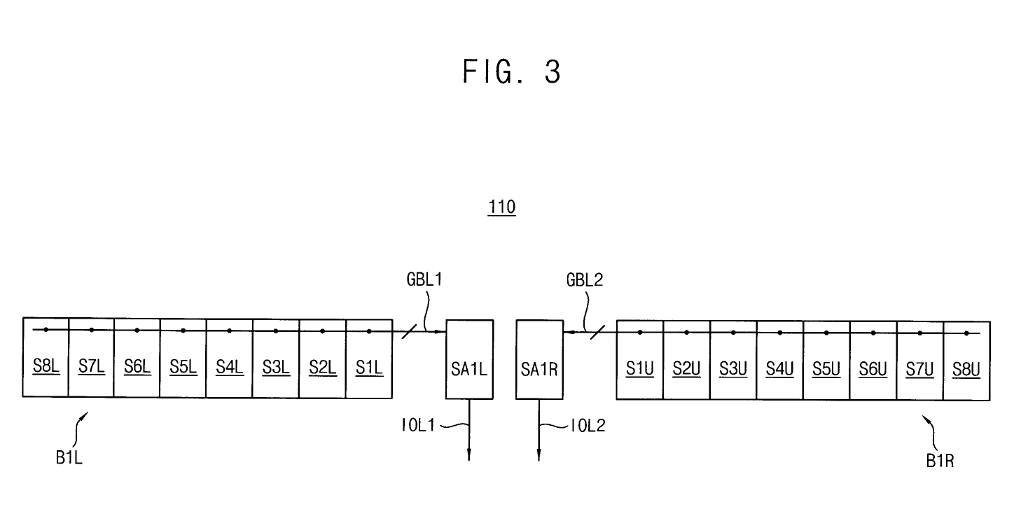

FIG. 3 is a block diagram illustrating one exemplary layout of sectors within memory banks included in the memory cell array of FIG. 2.

Referring to FIG. 3, first memory bank 110 includes the first sub-memory bank B1L, first sense amplifier SA1L, second sub-memory bank B1R and second sense amplifier SA1R. The first sub-memory bank B1L comprises first through eighth “lower sectors” S1L, S2L, S3L, S4L, S5L, S6L, S7L and S8L, and the second sub-memory bank B1R comprises first through eighth “upper sectors” S1U, S2U, S3U, S4U, S5U, S6U, S7U and S8U.

The first through eighth lower sectors S1L, S2L, S3L, S4L, S5L, S6L, S7L and S8L are coupled to the first sense amplifier SA1L via a first global bit line GBL1. An output signal from the first sense amplifier SA1L is provided by a first input/output line IOL1. The first through eighth upper sectors S1U, S2U, S3U, S4U, S5U, S6U, S7U and S8U are coupled to the second sense amplifier SA1R via a second global bit line GBL2. An output signal from the second sense amplifier SA1R is provided by a second input/output line IOL2.

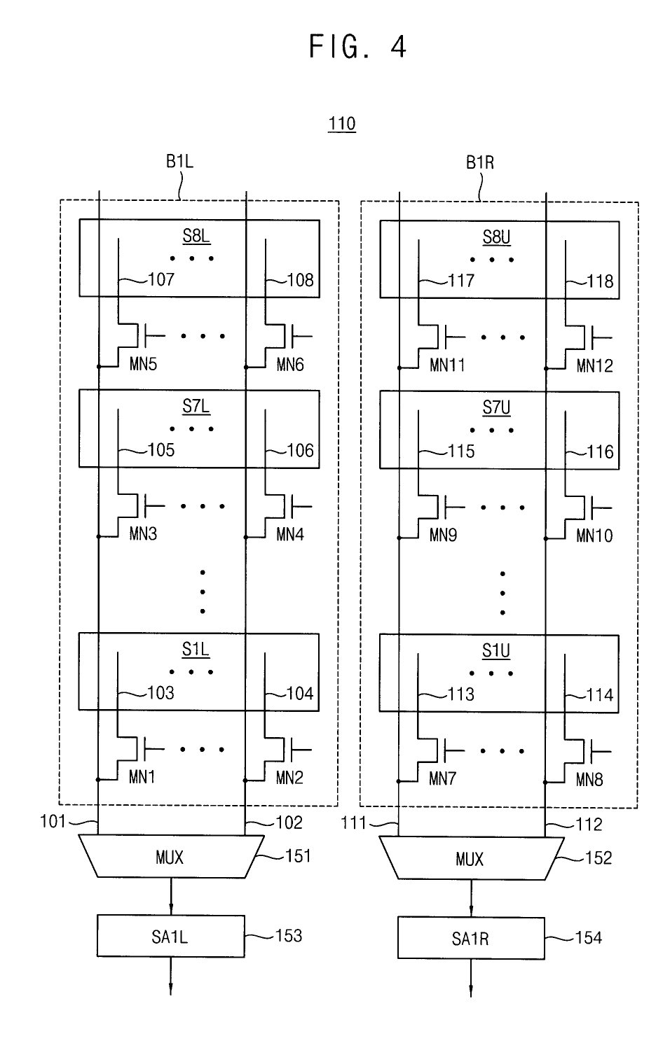

FIG. 4 is a circuit diagram further illustrating the memory bank of FIG. 3.

Referring to FIG. 4, first memory bank 110 includes the first sub-memory bank B1L, a first multiplexer 151, a first sense amplifier 153, the second sub-memory bank B1R, a second multiplexer 152 and a second sense amplifier 154. An output signal from first multiplexer 151 is amplified by first sense amplifier 153, and an output signal from second multiplexer 152 is amplified by second sense amplifier 154.

The first sub-memory bank B1L includes first through eighth lower sectors S1L, S2L, S3L, S4L, S5L, S6L, S7L and S8L. A first local bit line 103 disposed in relation to the first lower sector S1L is coupled to a first global bit line 101 through a first NMOS transistor MN1. A second local bit line 104 disposed in relation to the first lower sector S1L is coupled to a second global bit line 102 through a second NMOS transistor MN2. A third local bit line 105 dipsosed in relation to the seventh lower sector S7L is coupled to first global bit line 101 through a third NMOS transistor MN3, and a fourth local bit line 106 disposed in relation to the seventh lower sector S7L is coupled to second global bit line 102 through a fourth NMOS transistor MN4. A fifth local bit line 107 disposed in relation to the eighth lower sector S8L is coupled to first global bit line 101 through a fifth NMOS transistor MN5, and a sixth local bit line 108 disposed in relation to the eighth lower sector S8L is coupled to second global bit line 102 through a sixth NMOS transistor MN6.

The second sub-memory bank B1R includes first through eighth upper sectors S1U, S2U, S3U, S4U, S5U, S6U, S7U and S8U. A seventh local bit line 113 disposed in relation to the first upper sector S1U is coupled to a third global bit line 111 through a seventh NMOS transistor MN7, and an eighth local bit line 114 disposed in relation to the first upper sector S1U is coupled to a fourth global bit line 112 through an eighth NMOS transistor MN8. A ninth local bit line 115 disposed in relation to the seventh upper sector S7U is coupled to third global bit line 111 through a ninth NMOS transistor MN9, and a tenth local bit line 116 disposed in relation to the seventh upper sector S7U is coupled to fourth global bit line 112 through a tenth NMOS transistor MN10. An eleventh local bit line 117 disposed in relation to the eighth upper sector S8U is coupled to third global bit line 111 through an eleventh NMOS transistor MN11, and a twelfth local bit line 118 disposed in relation to the eighth upper sector S8U is coupled to fourth global bit line 112 through a twelfth NMOS transistor MN12.

Operations of first memory bank 110 will now be described with reference to FIG. 4.

Each of the local bit lines 103, 104, 105, 106, 107, 108, 113, 114, 115, 116, 117 and 118 is coupled to respectively corresponding memory cells. The first through sixth NMOS transistors MN1, MN2, MN3, MN4, MN5 and MN6 included in the first sub-memory bank B1L electrically couple the first through sixth local bit lines 103, 104, 105, 106, 107, 108 to either the first or second global bit lines 101 and 102 in response to control (i.e., select) signals. Similarly, the seventh through twelfth NMOS transistors MN7, MN8, MN9, MN10, MN11 and MN12 included in the second sub-memory bank B1R electrically couple the seventh through twelfth local bit lines 113, 114, 115, 116, 117 and 118 to either the third or fourth global bit lines 111 and 112 in response to select signals.

In FIG. 4, first multiplexer 151 selects either data apparent on first global bit line 101 or second global bit line 102, and then outputs the selected data. First sense amplifier 153 senses and amplifies the signal provided by first multiplexer 151. Second multiplexer 152 selects either data apparent on third global bit line 111 or fourth global bit line 112, and then outputs the selected data. Second sense amplifier 154 senses and amplifies the signal provided by second multiplexer 152.

While an architecture of first memory bank 110 illustrated in FIG. 4 includes first and second multiplexers 151 and 152, it will be understood by those skilled in the art that first memory bank 110 may be implemented without one or both of first and second multiplexers 151 and 152. For example, the multiplexing functionality may be directly incorporated within first and second sense amplifiers 153 and 154.

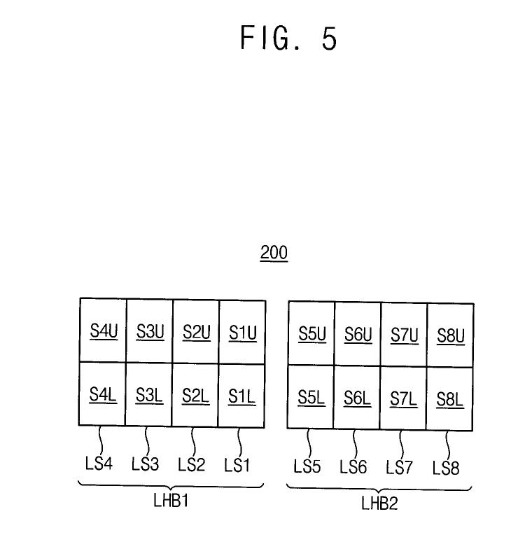

FIG. 5 is a block diagram further illustrating the plurality of sectors in the memory bank of FIG. 3.

Referring to FIG. 5, a memory bank 200 comprises a first logical half bank LHB1 and a second logical half bank LHB2. The first logical half bank LHB1 includes a first logical sector LS1, a second logical sector LS2, a third logical sector LS3 and a fourth logical sector LS4. The second logical half bank LHB2 includes a fifth logical sector LS5, a sixth logical sector LS6, a seventh logical sector LS7 and an eighth logical sector LS8.

The first logical sector LS1 includes a first lower sector S1L and a first upper sector S1U. Similarly, the second logical sector LS2 includes a second lower sector S2L and a second upper sector S2U. As such, the eighth logical sector LS8 includes an eighth lower sector S8L and an eighth upper sector S8U.

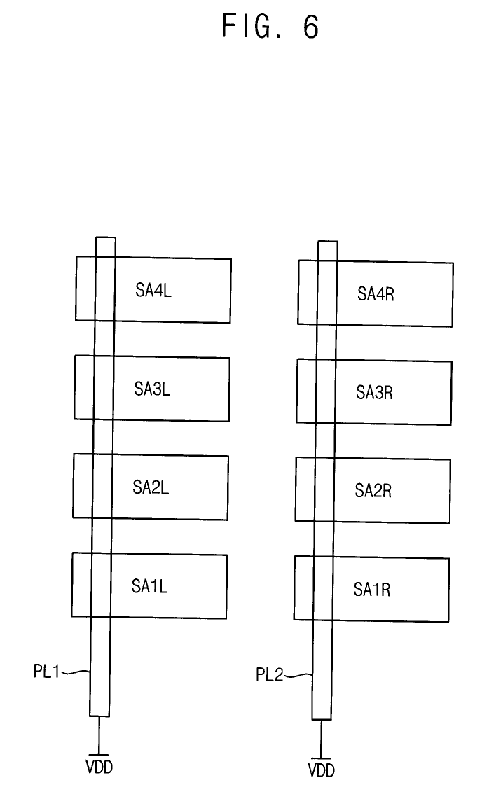

FIG. 6 is a diagram illustrating an exemplary layout of signal lines providing power supply voltages to sense amplifiers included within the memory cell array of FIG. 2.

Referring to FIG. 6, the first sense amplifier SA1L, third sense amplifier SA2L, fifth sense amplifier SA3L and a seventh sense amplifier SA4L are supplied with a high power supply voltage (e.g., VDD) via a first power line PL1. The second sense amplifier SA1R, fourth sense amplifier SA2R, sixth sense amplifier SA3R and eighth sense amplifier SA4R are supplied with the high power supply voltage (VDD) via a second power line PL2, separate from first power line PL1.

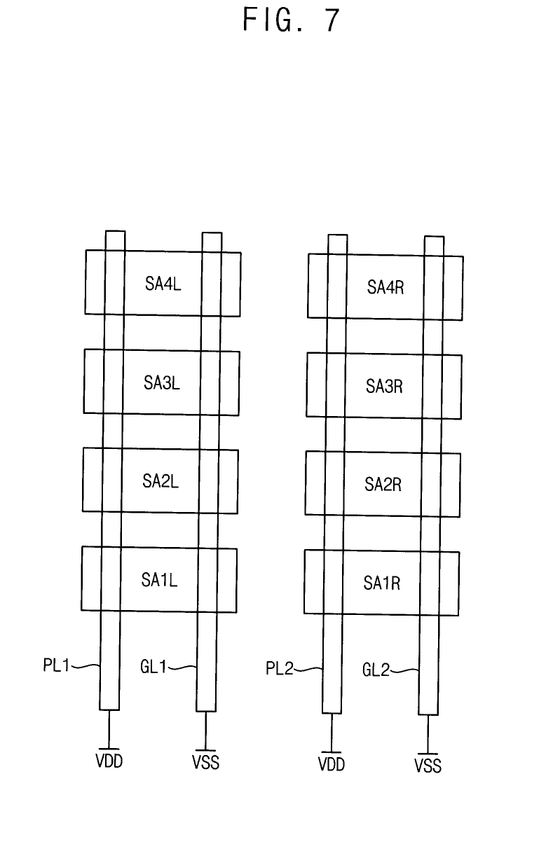

FIG. 7 is a diagram illustrating another exemplary layout of signal lines providing power supply voltages to sense amplifiers included in the memory cell array of FIG. 2.

Referring to FIG. 7, the first sense amplifier SA1L, third sense amplifier SA2L, fifth sense amplifier SA3L and seventh sense amplifier SA4L are supplied with high power supply voltage (VDD) via first power line PL1, and with a low power supply voltage (e.g., VSS) via a first ground line GL1. The second sense amplifier SA1R, fourth sense amplifier SA2R, sixth sense amplifier SA3R and eighth sense amplifier SA4R are supplied with the high power supply voltage (VDD) via second power line PL2, and with the low power supply voltage (VSS) via a second ground line GL2.

Hereinafter, one exemplary architecture for memory cell array 100 included within a flash memory device according to an embodiment of the invention will be described with collective reference to FIGS. 2 through 7.

Referring to FIG. 2, memory cell array 100 included in the flash memory device comprises a plurality of first through fourth memory banks 110, 120, 130 and 140. Each one of first through fourth memory banks 110, 120, 130 and 140 respectively comprises two (2) sub-memory banks and two (2) associated sense amplifiers.

For example, first memory bank 110 includes the first sub-memory bank B1L, first sense amplifier SA1L, second sub-memory bank B1R, and second sense amplifier SA1R. The first sense amplifier SA1L is associated with the first sub-memory bank B1L, and the second sense amplifier SA1R is associated with the second sub-memory bank B1R.

Referring to FIG. 3, the first sub-memory bank B1L includes (as physical sectors) the first lower sector S1L, second lower sector S2L, third lower sector S3L, fourth lower sector S4L, fifth lower sector S5L, sixth lower sector S6L, seventh lower sector S7L and eighth lower sector S8L. The second sub-memory bank B1R includes (as physical sectors) the first upper sector S1U, second upper sector S2U, third upper sector S3U, fourth upper sector S4U, fifth upper sector S5U, sixth upper sector S6U, seventh upper sector S7U and eighth upper sector S8U.

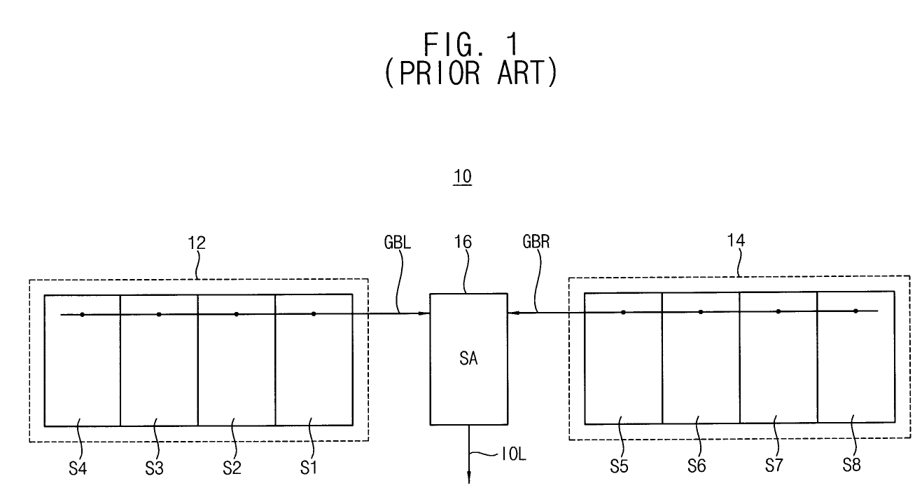

Of note, in the conventional memory cell array illustrated in FIG. 1, each one of the plurality of physical sectors S1, S2, S3, S4, S5, S6, S7 and S8 included in memory bank 10 has a similar respective logical layout. That is, physical and logical sector layout is the same.

However, in memory cell array 100 of FIG. 2 according to an embodiment of the invention, each of the sub-memory banks included in the first through fourth memory banks 110, 120, 130 and 140 comprises logical sectors that are non-aligned with corresponding physical sectors. For example and referring to FIG. 3, the first sub-memory bank B1L includes lower physical sectors S1L, S2L, S3L, S4L, S5L, S6L, S7L and S8L, while the second sub-memory bank B1R includes upper physical sectors S1U, S2U, S3U, S4U, S5U, S6U, S7U and S8U.

Referring to FIG. 5, each of the logical sectors within the exemplary memory bank comprises an upper physical sector and a lower physical sector included in a sub-memory bank in different rows, respectively. For example, first logical sector LS1 comprises first lower sector S1L and a first upper sector S1U. Second logical sector LS2 comprises second lower sector S2L and second upper sector S2U. Third logical sector LS3 comprises third lower sector S3L and third upper sector S3U. Fourth logical sector LS4 comprises fourth lower sector S4L and fourth upper sector S4U. Fifth logical sector LS5 comprises fifth lower sector S5L and fifth upper sector S5U. Sixth logical sector LS6 comprises sixth lower part S6L and sixth upper sector S6U. Seventh logical sector LS7 comprises seventh lower sector S7L and seventh upper sector S7U, and eighth logical sector LS8 comprises eighth lower sector S8L and eighth upper sector S8U.

Thus, in the example illustrated in FIGS. 3 and 5, each logical sector includes at least two (2) physical sectors, where one of the two (2) physical sectors is included in first sub-memory bank B1L and the other is included in second sub-memory bank B1R.

For example, first lower sector S1L of first logical sector LS1 is included in first sub-memory bank B1L, and first upper sector S1U of first logical sector LS1 is included in second sub-memory bank B1R. The second lower sector S2L of second logical sector LS2 is included in first sub-memory bank B1L, and second upper sector S2U of second logical sector LS2 is included in second sub-memory bank B1R. Similarly, eighth lower sector S8L of eighth logical sector LS8 is included in first sub-memory bank B1L, and eighth upper sector S8U of eighth logical sector LS8 is included in second sub-memory bank B1R.

In each memory bank included in the memory cell array according to an embodiment of the invention, given a number of physical sectors K (where K is a natural number) and a number of logical sectors L (where L is a natural number), the corresponding number of sub-memory banks M may be defined as (M=K/L).

In a typical flash memory device, program operations are performed according to memory bank units, while erase operations are performed according to sector units. Memory bank 110 illustrated in FIG. 3 includes the first sub-memory bank B1L implemented with lower logical sectors, second sub-memory bank B1R implemented with upper logical sectors, the first sense amplifier SA1L coupled to the first sub-memory bank B1L and the second sense amplifier SA1R coupled to the second sub-memory bank B1R. The first sense amplifier SA1L amplifies data provided from each sector of the first sub-memory bank B1L, and outputs the amplified data via first input/output line IOL1. The second sense amplifier SA1R amplifies data provided from each sector of the second sub-memory bank B1R, and outputs the amplified data via second input/output line IOL2.

In a typical non-volatile memory device, erase operations and read operations are performed according to logical sector units. In a memory cell array according to an embodiment of the invention, physical sectors constituting the same logical sector included in different sub-memory banks may be simultaneously accessed (at least substantially so) during a read operation.

As illustrated in FIG. 3, a size of each physical sector included in the sub-memory banks B1L and B1R may be substantially half that of each logical sector. That is, a circuit size of each of the lower sectors S1L, S2L, S3L, S4L, S5L, S6L, S7L and S8L and the upper sectors S1U, S2U, S3U, S4U, S5U, S6U, S7U and S8U included in memory bank 110 of FIG. 3 is half of a circuit size of each physical sector included in the conventional memory bank illustrated in FIG. 1. For example, a size of the physical sector S1 in memory bank 10 illustrated in FIG. 1 is the same as the sum of sizes of the first lower sector S1L and the first upper sector S1U in memory bank 110 illustrated in FIG. 3.

In FIG. 6, the first sense amplifier SA1L, third sense amplifier SA2L, fifth sense amplifier SA3L and seventh sense amplifier SA4L sense and amplify data related to the sub-memory banks B1L, B2L, B3L and B4L located at the one side of the memory cell array 100 of FIG. 2, respectively. The second sense amplifier SA1R, fourth sense amplifier SA2R, sixth sense amplifier SA3R and eighth sense amplifier SA4R sense and amplify data related to the sub-memory banks B1R, B2R, B3R and B4R located at the other side of the memory cell array 100 of FIG. 2, respectively. The sense amplifiers SA1L, SA2L, SA3L and SA4L are coupled to the sub-memory banks B1L, B2L, B3L and B4L, respectively. The sense amplifiers SA1R, SA2R, SA3R and SA4R are coupled to the sub-memory banks B1R, B2R, B3R and B4R, respectively.

The sense amplifiers SA1L, SA2L, SA3L and SA4L located at the one side of memory cell array 100 are supplied with high power supply voltage (VDD) via first power line PL1, and the sense amplifiers SA1R, SA2R, SA3R and SA4R located at the other side of memory cell array 100 are supplied with the high power supply voltage (VDD) via second power line PL2.

As described above, the sense amplifiers SA1L, SA2L, SA3L and SA4L located at the one side and the sense amplifiers SA1R, SA2R, SA3R and SA4R located at the other side are supplied the high power supply voltage (VDD) via different (and physically separated) power lines and/or different (and physically separated) ground lines, thereby dispersing peak power noise.

In FIG. 7, the sense amplifiers SA1L, SA2L, SA3L and SA4L located at the one side of memory cell array 100 are supplied with high power supply voltage (VDD) via first power line PL1 and with low power supply voltage (VSS) via first ground line GL1. The sense amplifiers SA1R, SA2R, SA3R and SA4R located at the other side of memory cell array 100 are supplied with the high power supply voltage (VDD) via a second power line PL2 and with the low power supply voltage (VSS) via a second ground line GL2.

As described above, the sense amplifiers SA1L, SA2L, SA3L and SA4L located at the one side and the sense amplifiers SA1R, SA2R, SA3R and SA4R located at the other side are supplied with the high power supply voltage (VDD) and/or the low power supply voltage (VSS) via different power lines and/or different ground lines, thereby dispersing a peak power noise.

Referring to FIGS. 2 through 7, a memory cell array according to an embodiment of the invention may implemented during flash memory device fabrication by a method that (1) divides each logical sector within a memory bank into two or more physical sectors; (2) defining a sub-memory bank based on physical sectors selected from different logical sectors; and (3) associating sense amplifiers with each one of the sub-memory banks.

In a method of operating a memory cell array according to an embodiment of the invention, the logical sector may be the memory cell array unit defining an erase operation or a read operation within the non-volatile semiconductor memory device. In a method of operating a memory cell array according to an embodiment of the invention, physical sectors constituting one logical sector included in different sub-memory banks may be simultaneously accessed during a read operation. Also, in a method of operating a memory cell array according to an embodiment of the invention, the physical sectors may be supplied with power via separate power lines.

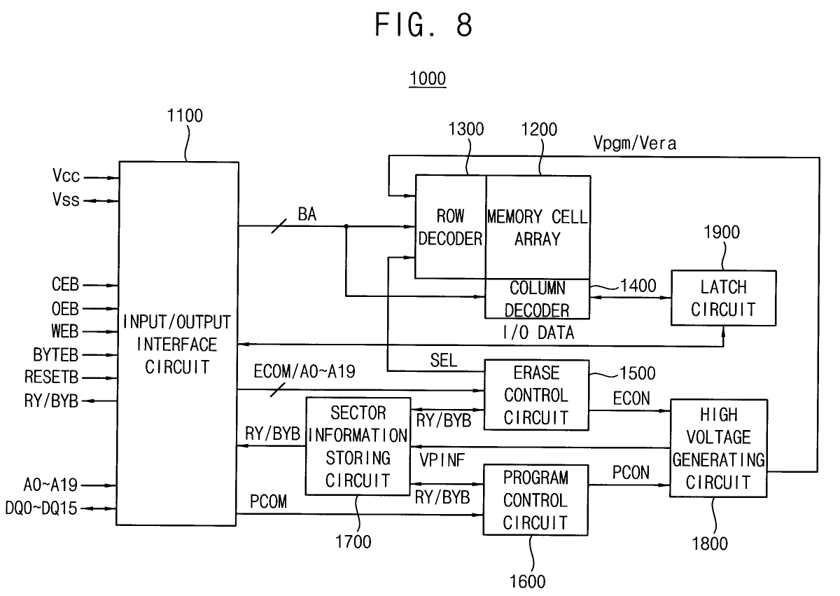

FIG. 8 is a block diagram illustrating an exemplary flash memory device including the memory cell array such as the one described in relation to FIG. 2 according to an embodiment of the invention.

Referring to FIG. 8, a flash memory device 1000 includes an input/output interface circuit 1100, a memory cell array 1200, a row decoder 1300, a column decoder 1400, an erase control circuit 1500, a program control circuit 1600, a sector information storing circuit 1700, a high voltage generating circuit 1800 and a latch circuit 1900.

Input/output interface circuit 1100 receives control signals CEB, OEB, WEB, BYTEB, RESETB, RY and BYB, data DQ0 through DQ15 and addresses A0 through A19, and generates a bank address BA for selecting one of the memory banks constituting the memory cell array 1200, a program command PCOM and an erase command ECOM. Memory cell array 1200 may have a configuration illustrated in FIG. 2. Memory cell array 1200 may include a plurality of memory banks.

Each memory bank includes a plurality of sectors each of which has a plurality of memory cells. Row decoder 1300 generates a word line drive signal by decoding the bank address BA in response to a program voltage Vpgm or an erase voltage Vera. Column decoder 1400 generates a column select signal by decoding the bank address BA. The word line drive signal and the column select signal are applied to memory cell array 1200. Erase control circuit 1500 generates an erase control signal ECON and a select signal SEL based on the erase command ECOM, a busy signal BYB and a ready signal RY. Program control circuit 1600 generates a program control signal PCON based on the program command PCOM, the busy signal BYB and the ready signal RY.

Sector information storing circuit 1700 stores information on sectors constituting memory cell array 1200. High voltage generating circuit 1800 generates the program voltage Vpgm or the erase Voltage Vera based on the program control signal PCON and the erase control signal ECON when the program operation or the erase operation is performed. Latch circuit 1900 provides data I/O DATA received from the input/output interface circuit 1100 to the memory cell array 1200 through the column decoder 1400 during the program operation. Also, when the read operation is performed, latch circuit 1900 receives data I/O DATA from memory cell array 1200 through column decoder 1400, and provides the received data to input/output interface circuit 1100.

In flash memory device 1000 of FIG. 8, memory cell array 1200 may have a memory bank architecture illustrated in FIG. 3. Memory cell array 1200 includes a plurality of memory banks each of which includes a plurality of logical sectors, and each logical sector includes a plurality of physical sectors, or parts of the logical sectors. The memory cell array 1200 includes a plurality of sense amplifiers dedicated to the sub-memory banks, respectively.

As mentioned above, in the memory cell array according to some example embodiments, a logical sector is divided into a plurality of physical sectors, and the physical sectors constituting one logical sector are included in different sub-memory banks. The memory cell array according to embodiments of the invention includes independent sense amplifiers according to sub-memory banks. Therefore, the memory cell array according to an embodiment of the invention reduces power noise and improves electrical signal coupling characteristics.

While the foregoing embodiments and their advantages have been described in detail, it should be understood that various changes, substitutions and alterations may be made herein without departing from the scope of the invention.

What is claimed is:

1. A memory cell array having a plurality of memory banks, each memory bank including a plurality of logical sectors, the memory cell array comprising:
a plurality of sub-memory banks, wherein each one of the plurality of sub-memory banks includes a plurality of physical sectors, and each one of the plurality of physical sectors is part of one of the plurality of logical sectors; and
a plurality of sense amplifiers respectively associated with the plurality of sub-memory banks.

2. The memory cell array of claim 1, wherein each one of the plurality of logical sectors is a memory cell array unit defining an erase operation or a read operation.

3. The memory cell array of claim 1, wherein a number of the sub-memory banks included in each memory bank is defined by dividing a number of physical sectors included in the memory bank by a number of logical sectors included in the memory bank.

4. The memory cell array of claim 1, wherein the physical sectors respectively included in the sub-memory banks are simultaneously accessed during a read operation.

5. The memory cell array of claim 4, wherein at least two physical sectors of the plurality of physical sectors simultaneously accessed during the read operation are included in a single logical sector of the plurality of logical sectors.

6. The memory cell array of claim 1, further comprising:
power lines configured to provide a power supply voltage to the plurality of sub-memory banks, wherein the power lines are physically separated from each other.

7. The memory cell array of claim 1, further comprising:
first and second power lines configured to provide a high power supply voltage to the plurality of sub-memory banks, wherein the first and second power first lines are physically separated from each other; and
first and second ground lines configured to provide a low power supply voltage to the plurality of sub-memory banks, wherein the first and second power lines are physically separated from each other.

8. The memory cell array of claim 1, wherein each of the plurality of logical sectors includes two physical sectors of the plurality of physical sectors.

9. The memory cell array of claim 8, wherein each memory bank includes two sub-memory banks.

10. The memory cell array of claim 8, wherein each memory bank comprises:
a first sub-memory bank including a plurality of lower sectors, wherein each one of the plurality of lower sectors is one of the two physical sectors;
a first sense amplifier configured to amplify an output signal provided by the first sub-memory bank, and output the amplified output signal via a first input/output line;
a second sub-memory bank including a plurality of upper sectors, wherein each one of the plurality of upper sectors is the other of the two physical sectors; and
a second sense amplifier configured to amplify an output signal provided by the second sub-memory bank, and output the amplified output signal via a second input/output line.

11. The memory cell array of claim 10, wherein a first lower sector of the plurality of lower sectors included in the first sub-memory bank and a first upper sector of the plurality of upper sectors included in the second sub-memory bank are simultaneously accessed during a read operation.

12. The memory cell array of claim 10, further comprising:
a first power line configured to provide a power supply voltage to the plurality of lower sectors included in the first sub-memory bank; and
a second power line configured to provide the power supply voltage to the plurality of upper sectors included in the second sub-memory bank,
wherein the second power line is physically separated from the first power line.

13. The memory cell array of claim 10, further comprising:
a first power line configured to provide a high power supply voltage to the plurality of lower sectors included in the first sub-memory bank;
a second power line configured to provide the high power supply voltage to the plurality of upper sectors included in the second sub-memory bank;
a first ground line configured to provide a low power supply voltage to the plurality of lower sectors included in the first sub-memory bank; and
a second ground line configured to provide the low power supply voltage to the plurality of upper sectors included in the second sub-memory bank,
wherein the second power line is physically separated from the first power line and the first ground line is physically separated from the second ground line.

14. A non-volatile memory device, comprising:
a voltage generating circuit configured to generate a program voltage or an erase voltage in response to receipt of a program control signal or an erase control signal;
a row decoder configured to generate a word line drive signal based on a bank address and at least one of the program voltage and the erase voltage;
a column decoder configured to generate a column select signal by decoding the bank address; and
a memory cell array configured to operate in response to the word line drive signal and the column select signal, the memory cell array comprising:
a plurality of sub-memory banks, each of the plurality of sub-memory banks including a plurality of physical sectors, each of the plurality of physical sectors being a part of one of the plurality of logical sectors; and
a plurality of sense amplifiers respectively associated with the plurality of sub-memory banks.

15. The non-volatile memory device of claim 14, wherein the memory cell array further comprises; first and second power lines configured to provide a power supply voltage to the plurality of sub-memory banks, wherein the first and second power lines are physically separated from each other.
